(19) United States
(12) Patent Application Publication
(10) Pub. No.: US 2021/0152745 A1
(43) Pub. Date: May 20, 2021

(54) Defect Observation Machine and Image Analysis and Compensation Method Thereof

(71) Applicant: Shanghai Huali Microelectronics Corporation, Shanghai (CN)

(72) Inventor: Yunwei Ding, Shanghai (CN)

(73) Assignee: Shanghai Huali Microelectronics Corporation, Shanghai (CN)

(21) Appl. No.: 16/800,282

(22) Filed: Feb. 25, 2020

(30) Foreign Application Priority Data
Nov. 19, 2019 (CN) 201911133518.1

(51) Int. Cl. H04N 5/232; G06K 9/00; G06K 9/62

(52) U.S. Cl. CPC H04N 5/232127; G06K 9/00134; G06K 2209/19; H04N 5/23218; G06K 9/6212

(57) ABSTRACT

Embodiments described herein relate to a defect observation machine and an image analysis and compensation method thereof. By embedding a real-time image analysis unit in a defect observation machine, analyzing and judging a defect pattern picture outputted by a defect observation unit in real time, and feeding back a focusing compensation value of a blurred defect pattern picture to the defect observation unit to perform focusing compensation on the blurred defect pattern picture, a clear photo is presented.

### CROSS REFERENCE TO RELATED APPLICATIONS

The present application claims priority to and the benefit of Chinese Patent Application No. 201911133518.1 filed on Nov. 19, 2019, the disclosure of which is incorporated herein by reference in its entirety as part of the present application.

### BACKGROUND

The disclosure relates to defect observation technology, in particular to a defect observation machine and an image analysis and compensation method thereof.

With the development of semiconductor technology, the demand for chip yield rate is getting higher and higher. However, the integrated circuit chip manufacturing process is complex and many defects are often produced during manufacturing, thus defect observation is an essential process during manufacturing of integrated circuits.

As the semiconductor industry technology becomes more mature and advanced, the line width becomes smaller, the density becomes higher, and the corresponding defects become smaller. More requirements are put forward for defect observation. In the current defect observation machine (SEMVision), when some special products and special sheet material products are observed, the defect image is often blurred. Such products with blurred images need to be re-observed through artificial focusing. There will be a certain impact on the production capacity of the machine. For serious defect problems, such repeated observations cannot meet the timeliness. For details, please refer to the defect observation method of the prior art shown in FIG. 1.

### BRIEF SUMMARY

According to embodiments described herein there is provided a defect observation machine. The defect observation machine having a function of analyzing and compensating for a defect pattern picture in real time so that the defect pattern picture outputted by the defect observation machine is a clear defect pattern picture, wherein the defect observation machine comprises: a defect observation unit, which is used to perform defect pattern observation on a semiconductor product through a focusing value and output the defect pattern picture; and a real-time image analysis unit, which is used to pre-store an average pixel value and data of a correspondence between a pixel difference and a focusing compensation value of a clear defect pattern picture, receive the defect pattern picture, perform data analysis on the defect pattern picture to obtain an average pixel value of the defect pattern picture, compare the average pixel value of the defect pattern picture and the average pixel value of the corresponding clear defect pattern picture to obtain a pixel difference, judge the pixel difference, output the received defect pattern picture as a final defect pattern picture if the absolute value of the pixel difference is less than or equal to a threshold, search for a corresponding focusing compensation value from the data of the correspondence between the pixel difference and the focusing compensation value according to the pixel difference if the absolute value of the pixel difference is greater than the threshold, output the focusing compensation value to the defect observation unit, such that the defect observation unit adjusts a focusing value of the defect observation unit by using the focusing compensation value and then keeps observing the same defect pattern and again outputs a defect pattern picture to the real-time image analysis unit.

According to embodiments described herein there is provided an image analysis and compensation method of a defect observation machine, wherein the method comprises: S1: a defect observation unit performing defect pattern observation on a semiconductor product through a focusing value, so as to output a defect pattern picture; S2: a real-time image analysis unit receiving the defect pattern picture, and performing data analysis on the defect pattern picture to obtain an average pixel value of the defect pattern picture; S3: pre-storing in the real-time image analysis unit an average pixel value of a clear picture of a defect pattern and data of a correspondence between a pixel difference and a focusing compensation value; and S4: comparing the average pixel value of the defect pattern picture and the average pixel value of the corresponding clear picture of the defect pattern to obtain a pixel difference, the real-time image analysis unit judging the pixel difference, the real-time image analysis unit outputting the received defect pattern picture as a final defect pattern picture if the absolute value of the pixel difference is less than or equal to a threshold, the real-time image analysis unit searching for a corresponding focusing compensation value from the data of the correspondence between the pixel difference and the focusing compensation value according to the pixel difference if the absolute value of the pixel difference is greater than the threshold, and outputting the focusing compensation value to the defect observation unit, such that the defect observation unit adjusts a focusing value of the defect observation unit by using the focusing compensation value and then keeps observing the same defect pattern and again outputs a defect pattern picture to the real-time image analysis unit.

### BRIEF DESCRIPTION OF THE DRAWINGS

FIG. 1 is a defect observation method of the prior art.

FIG. 2 shows different embodiments of common blurs in a defect pattern picture.

FIG. 3 is a schematic view of a defect observation machine according to an embodiment of the present disclosure.

FIG. 4a is a schematic view of obtaining an average pixel value of a defect pattern picture according to an embodiment of the present disclosure.

FIG. 4b is a schematic view of obtaining an average pixel value of a defect pattern picture according to an embodiment of the present disclosure.

FIG. 4c is a schematic view of obtaining an average pixel value of a defect pattern picture according to an embodiment of the present disclosure.

FIG. 5a and FIG. 5b are schematic views of obtaining an average pixel value of a clear picture of the defect pattern according to an embodiment of the present disclosure.

FIG. 6 is a schematic view of data of a correspondence between a pixel difference and a focusing compensation value according to an embodiment of the present disclosure.

FIG. 7 is a schematic view of a process of analyzing and compensating a defect image in real time by using the defect observation machine of the present disclosure.

Reference numerals of main elements in the figures are described as follows:

300—defect observation machine; 310—defect observation unit; 320—real-time image analysis unit.

### DETAILED DESCRIPTION

The technical solutions in the present disclosure will be clearly and fully described below with reference to the drawings. Apparently, described embodiments are only part of rather than all of the embodiments of the present disclosure. All other embodiments obtained by those ordinarily skilled in the art based on the embodiments in the present disclosure without creative efforts fall within the protection scope of the present disclosure.

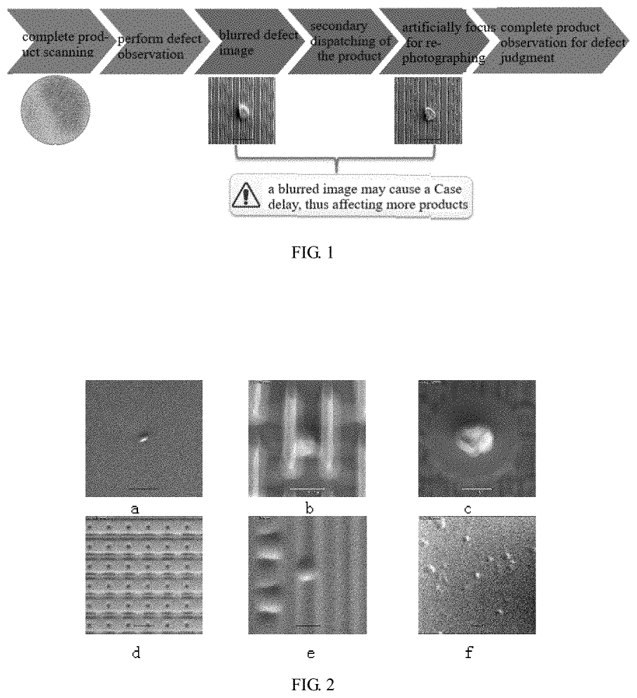

Specifically, please refer to FIG. 2 which shows different embodiments of common blurred defect pattern pictures. FIG. 2a shows a polished section site where an oxide layer is on the surface and there are no patterns, which will easily cause a blurred defect pattern picture. FIG. 2b shows a small type of defect with a defect size of less than 0.2 um, which will easily cause a blurred defect pattern picture. FIG. 2c shows that there is a hierarchical defect and it is difficult to be focused, which will easily cause a blurred defect pattern picture. FIG. 2d shows a photoresist site where a thick layer of photoresist is on the surface, which will easily cause a blurred defect pattern picture. FIG. 2e shows a thick site of 5-ThinDEP with a defect having thick wrapping, which will easily cause a blurred defect pattern picture. FIG. 2f shows dense defects where there are many types of defects on the surface, which will easily cause a blurred defect pattern picture. Apparently, the present disclosure does not exhaust all defect types, and all defects that easily cause a blurred defect pattern picture are within the protection scope of the present disclosure.

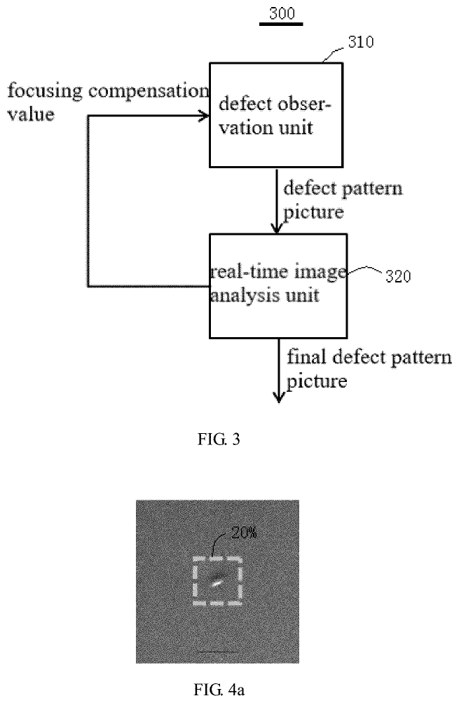

In one embodiment of the present disclosure, a defect observation machine is provided. The defect observation machine has a function of analyzing and compensating for a defect pattern picture in real time so that the defect pattern picture outputted by the defect observation machine is a clear defect pattern picture. Specifically, a reference can be made to FIG. 3 which is a schematic view of a defect observation machine according to one embodiment of the present disclosure. As shown in FIG. 3, the defect observation machine 300 comprises: a defect observation unit 310, which is used to perform defect pattern observation on a semiconductor product through a focusing value and output a defect pattern picture; and a real-time image analysis unit 320, which is used to pre-store an average pixel value of a clear picture of a defect pattern and data of a correspondence between a pixel difference and a focusing compensation value, receive the defect pattern picture, perform data analysis on the defect pattern picture to obtain an average pixel value of the defect pattern picture, compare the average pixel value of the defect pattern picture and the average pixel value of the corresponding clear picture of the defect pattern to obtain a pixel difference, judge the pixel difference, output the received defect pattern picture as a final defect pattern picture if the absolute value of the pixel difference is less than or equal to a threshold, search for a corresponding focusing compensation value from the data of the correspondence between the pixel difference and the focusing compensation value according to the pixel difference if the absolute value of the pixel difference is greater than the threshold, output the focusing compensation value to the defect observation unit 310, such that the defect observation unit 310 adjusts a focusing value of the defect observation unit 310 by using the focusing compensation value and then keeps observing the same defect pattern and again outputs a defect pattern picture to the real-time image analysis unit 320.

In this way, by embedding a real-time image analysis unit in a defect observation machine, analyzing and judging a defect pattern picture outputted by a defect observation unit in real time, and feeding back a focusing compensation value of the blurred defect pattern picture to the defect observation unit to perform focusing compensation on the blurred defect pattern picture, a clear photo is presented, thereby completing semiconductor product operations without artificial focusing for re-observation. The timeliness is high.

Specifically, in one embodiment of the present disclosure, the defect observation unit 310 is an electron microscope. Apparently, the present disclosure is not so limited, and any device that can take a photo of a defect pattern to form a defect pattern picture is possible.

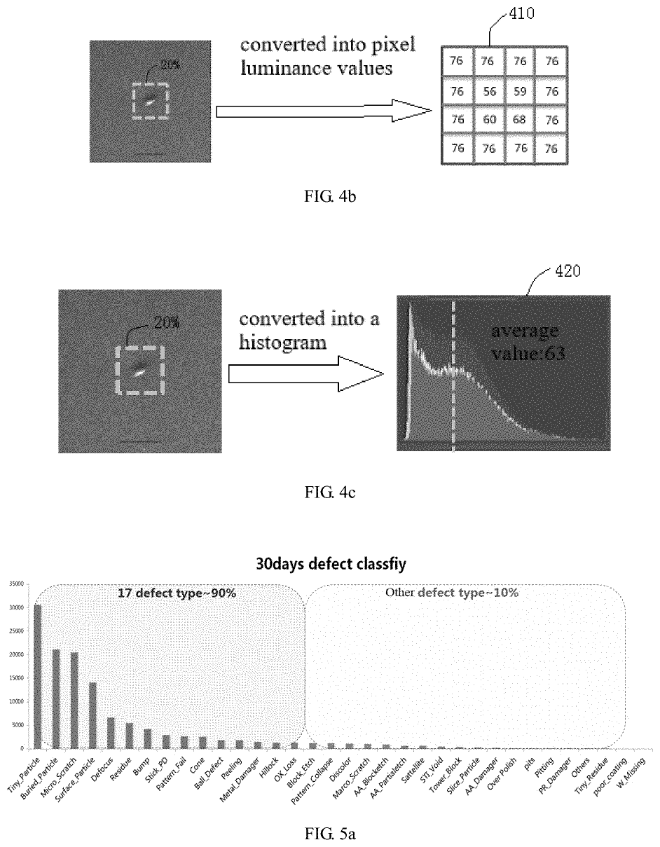

Specifically, in one embodiment of the present disclosure, the real-time image analysis unit 320 selects 20% of a central portion of the received defect pattern picture, and obtains an average pixel value of the defect pattern picture within the range of 20% as the average pixel value of the defect pattern picture. Specifically, a reference can be made to FIG. 4a which shows a schematic view of obtaining an average pixel value of a defect pattern picture according to one embodiment of the present disclosure. Based on a research, the defect is positioned at the 20% of the central portion of the defect pattern picture, and all information of the defect pattern can be included here. More specifically, in one embodiment of the present disclosure, the defect pattern picture within the range of 20% is divided into n*n units to obtain pixel values of the n*n units for converting the defect pattern picture within the range of 20% into data of luminance values of n*n pixels, so as to calculate an average value of pixel values of the data of luminance values of n*n pixels as the average pixel value of the defect pattern picture. Specifically, a reference can be made to FIG. 4b which shows a schematic view of obtaining an average pixel value of a defect pattern picture according to one embodiment of the present disclosure. The reference numeral 410 indicates data of luminance values of 4*4 pixels. More specifically, in one embodiment of the present disclosure, the defect pattern picture within the range of 20% is divided into n*n units to obtain pixel values of the n*n units for converting the defect pattern picture within the range of 20% into a histogram with abscissas indicating luminance and ordinates indicating pixel values, so as to obtain the average pixel value of the defect pattern picture according to the histogram. Specifically, a reference can be made to FIG. 4c which shows a schematic view of obtaining an average pixel value of a defect pattern picture according to one embodiment of the present disclosure. The reference numeral 420 indicates a histogram.

Specifically, in one embodiment of the present disclosure, the average pixel value of the clear picture of the defect pattern comprises average pixel values of clear pictures of the defect pattern of defects of 90% of all in-line defect types, so that defect pattern pictures of about 90% of defects can be made clear through the defect observation machine 300 of the present disclosure. Specifically, a reference can be made to FIG. 5a and FIG. 5b which show a schematic view of obtaining an average pixel value of a clear picture of the defect pattern according to one embodiment of the present disclosure. As shown in FIG. 5a, a classification situation of in-line defects in 30 days is statistically analyzed. It is found that 17 defect types account for about 90% of all defect types. Moreover, a reference is made to FIG. 5b. Average pixel values of the clear pictures of the defect pattern of the 17 defect types are obtained according to in-line data, and are pre-stored in the real-time image analysis unit 320 as pre-stored average pixel values of the clear pictures of the defect pattern. In this way, the defect pattern pictures of the about 90% of defects are analyzed and judged in real time by the real-time image analysis unit 320 shown in FIG. 3, and the focusing compensation value of the blurred defect pattern picture is fed back to the defect observation unit for performing focusing compensation on the blurred defect pattern picture, so as to present a clear photo. In this manner, the defect pattern pictures of about 90% of defects can be made clear.

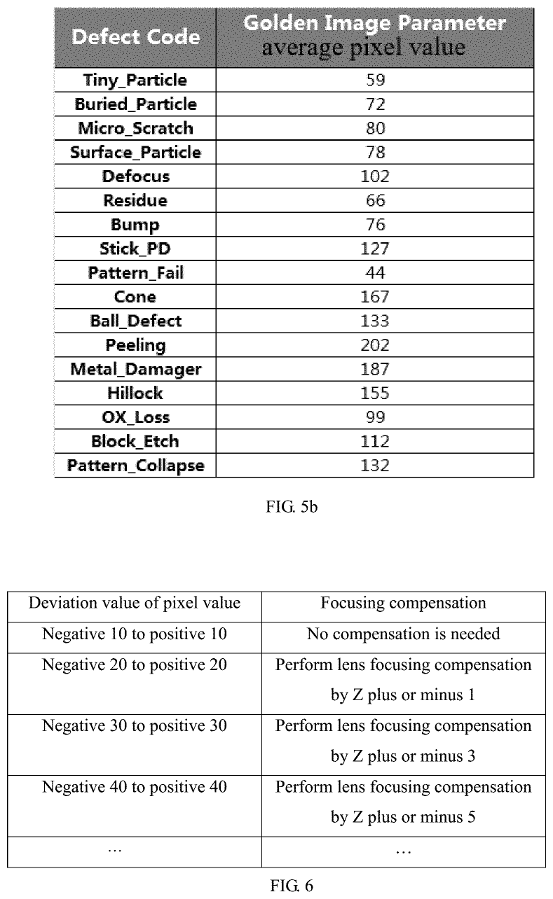

Specifically, in one embodiment of the present disclosure, an average pixel value of a blurred in-line defect pattern picture and an average pixel value of a clear defect pattern picture resulting from compensation are counted to obtain a pixel difference, and a focusing compensation value for compensating the blurred defect pattern picture as the clear defect pattern picture is counted, so as to obtain data of a correspondence between the pixel difference and the focusing compensation value, and the data is pre-stored in the real-time image analysis unit 320 as the data of the correspondence between the pixel difference and the focusing compensation value. Specifically, in one embodiment of the present disclosure, the pixel difference comprises a plurality of ranges wherein each corresponding to one focusing compensation value. In this way, a corresponding focusing compensation value can be selected, according to a pixel difference between an average pixel value of each defect pattern picture and a pre-stored average pixel value of a corresponding clear picture of the defect pattern, to compensate for the focusing value of the defect observation unit 310. Specifically, in one embodiment of the present disclosure, when the pixel difference is negative, the focusing compensation value is positive, and when the pixel difference is positive, the focusing compensation value is negative. Specifically, a reference can be made to FIG. 6 which shows a schematic view of data of a correspondence between a pixel difference and a focusing compensation value according to one embodiment of the present disclosure. As depicted in FIG. 6, when the pixel difference ranges between negative 10 and positive 10, there is no need to compensate for the focusing value, and the real-time image analysis 320 outputs the received defect pattern picture as the final defect pattern picture; when the pixel differences ranges between negative 20 and positive 20, the focusing compensation value is plus or minus 1, wherein when the pixel difference ranges between negative 20 and 0, the focusing compensation value is plus 1, and when the pixel difference ranges between 0 and positive 20, the focusing compensation value is minus 1; when the pixel difference ranges between negative 30 and positive 30, the focusing compensation value is plus or minus 3; and when the pixel difference ranges between negative 40 and positive 40, the focusing compensation value is plus or minus 5. In this way, a corresponding focusing compensation value is searched from the data of the correspondence between the pixel difference and the focusing compensation value according to the pixel difference obtained by the real-time image analysis unit 320, so as to convert the originally blurred defect pattern picture as a clear defect pattern picture.

In one embodiment of the present disclosure, the threshold is obtained through definition experiments and analyses of various in-line defect pattern pictures. In one embodiment of the present disclosure, the threshold is 10. The threshold may have a certain deviation. In one embodiment of the present disclosure, the deviation is within 20%, more preferably within 10%, even more preferably within 5%.

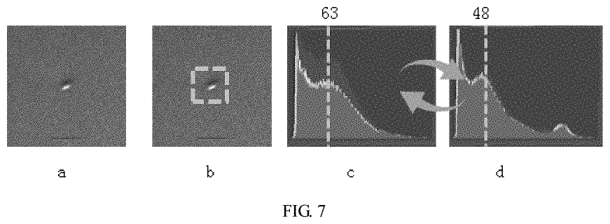

In one detailed embodiment of the present disclosure, a reference can be made to FIG. 7 which shows a schematic view of a process of analyzing and compensating for a defect image in real time by using the defect observation machine of the present disclosure. The defect observation unit 310 outputs a defect pattern picture shown in FIG. 7a. The real-time image analysis unit 320 selects 20% of a central portion of the defect pattern picture shown in FIG. 7a, as shown in FIG. 7b, and obtains an average pixel value of the defect pattern picture, as shown in FIG. 7c, the average pixel value is 63. Moreover, an average pixel value corresponding to the defect pattern picture is found in pre-stored average pixel values of clear pictures of the defect pattern in the real-time image analysis unit 320, as shown in FIG. 7d, the average pixel value is 48. It is determined that the pixel difference is 15, which is greater than 10. A focusing compensation value corresponding to the pixel difference of 15 is found to be minus 1 from data of a correspondence between pixel differences and focusing compensation values. The focusing compensation value is outputted to the defect observation unit 310. The defect observation unit 310 decreases the focusing value of the defect observation unit 310 by 1 according to the focusing compensation value, and then keeps observing the same defect pattern and again outputs a defect pattern picture. Then the above-mentioned steps are repeated until the absolute value of the pixel difference is less than the threshold of 10. The real-time image analysis unit 320 outputs the received defect pattern picture as the final defect pattern picture.

In one embodiment of the present disclosure, an image analysis and compensation method of a defect observation machine is further provided. The image analysis and compensation method of a defect observation machine comprises:

S1: A defect observation unit performing defect pattern observation on a semiconductor product through a focusing value, so as to output a defect pattern picture;

Specifically, in one embodiment of the present disclosure, the defect observation unit is an electron microscope. Apparently, the present disclosure is not so limited, and any device that can take a photo of a defect pattern to form a defect pattern picture is possible.

S2: A real-time image analysis unit receiving the defect pattern picture, and performing data analysis on the defect pattern picture to obtain an average pixel value of the defect pattern picture;

Specifically, in one embodiment of the present disclosure, the real-time image analysis unit selects 20% of a central portion of the received defect pattern picture, and obtains an average pixel value of the defect pattern picture within the range of 20% as the average pixel value of the defect pattern picture. Specifically, a reference can be made to FIG. 4a. Based on a research, the defect is positioned at the 20% of the central portion of the defect pattern picture, and all information of the defect pattern can be included here. More specifically, in one embodiment of the present disclosure, the defect pattern picture within the range of 20% is divided into n*n units to obtain pixel values of the n*n units for converting the defect pattern picture within the range of 20% into data of luminance values of n*n pixels, so as to calculate an average value of pixel values of the data of luminance values of n*n pixels as the average pixel value of the defect pattern picture. Specifically, a reference can be made to FIG. 4b. The reference numeral 410 indicates data of luminance values of 4*4 pixels. More specifically, in one embodiment of the present disclosure, the defect pattern picture within the range of 20% is divided into n*n units to obtain pixel values of the n*n units for converting the defect pattern picture within the range of 20% into a histogram with abscissas indicating luminance and ordinates indicating pixel values, so as to obtain the average pixel value of the defect pattern picture according to the histogram. Specifically, a reference can be made to FIG. 4c. The reference numeral 420 indicates a histogram.

S3: Pre-storing in the real-time image analysis unit an average pixel value of a clear picture of a defect pattern and data of a correspondence between a pixel difference and a focusing compensation value;

Specifically, in one embodiment of the present disclosure, the average pixel value of the clear picture of the defect pattern comprises average pixel values of clear pictures of the defect pattern of defects of 90% of all in-line defect types, so that defect pattern pictures of about 90% of defects can be made clear through the image analysis and compensation method of the defect observation machine of the present disclosure. Specifically, a reference can be made to FIG. 5a and FIG. 5b. As shown in FIG. 5a, a classification situation of in-line defects in 30 days is statistically analyzed. It is found that 17 defect types account for about 90% of all defect types. Moreover, a reference is made to FIG. 5b. Average pixel values of the clear pictures of the defect pattern of the 17 defect types are obtained according to in-line data, and are pre-stored in the real-time image analysis unit as pre-stored average pixel values of the clear pictures of the defect pattern.

Specifically, in one embodiment of the present disclosure, an average pixel value of a blurred in-line defect pattern picture and an average pixel value of a clear defect pattern picture resulting from compensation are counted to obtain a pixel difference, and a focusing compensation value for compensating the blurred defect pattern picture as the clear defect pattern picture is counted, so as to obtain data of a correspondence between the pixel difference and the focusing compensation value, and the data is pre-stored in the real-time image analysis unit as the data of the correspondence between the pixel difference and the focusing compensation value. Specifically, in one embodiment of the present disclosure, the pixel difference comprises a plurality of ranges wherein each corresponding to one focusing compensation value.

S4: Comparing the average pixel value of the defect pattern picture and the average pixel value of the corresponding clear picture of the defect pattern to obtain a pixel difference, the real-time image analysis unit judging the pixel difference, the real-time image analysis unit outputting the received defect pattern picture as a final defect pattern picture if the absolute value of the pixel difference is less than or equal to a threshold, the real-time image analysis unit searching for a corresponding focusing compensation value from the data of the correspondence between the pixel difference and the focusing compensation value according to the pixel difference if the absolute value of the pixel difference is greater than the threshold, and outputting the focusing compensation value to the defect observation unit, such that the defect observation unit adjusts the focusing value of the defect observation unit by using the focusing compensation value and then keeps observing the same defect pattern and again outputs a defect pattern picture to the real-time image analysis unit.

In this way, a corresponding focusing compensation value can be selected, according to a pixel difference between an average pixel value of each defect pattern picture and a pre-stored average pixel value of a corresponding clear picture of the defect pattern, to compensate for the focusing value of the defect observation unit. Accordingly, defect pattern pictures of about 90% of defects can be analyzed and judged in real time, and a focusing compensation value of a blurred defect pattern picture is fed back to the defect observation unit to perform focusing compensation on the blurred defect pattern picture, so as to present a clear photo. In this manner, defect pattern pictures of about 90% of defects can be made clear.

Specifically, in one embodiment of the present disclosure, when the pixel difference is negative, the focusing compensation value is positive, and when the pixel difference is positive, the focusing compensation value is negative. Specifically, a reference can be made to FIG. 6. When the pixel difference ranges between negative 10 and positive 10, there is no need to compensate for the focusing value, and the real-time image analysis outputs the received defect pattern picture as the final defect pattern picture; when the pixel differences ranges between negative 20 and positive 20, the focusing compensation value is plus or minus 1, wherein when the pixel difference ranges between negative 20 and 0, the focusing compensation value is plus 1, and when the pixel difference ranges between 0 and positive 20, the focusing compensation value is minus 1; when the pixel difference ranges between negative 30 and positive 30, the focusing compensation value is plus or minus 3; and when the pixel difference ranges between negative 40 and positive 40, the focusing compensation value is plus or minus 5. In this way, a corresponding focusing compensation value is searched from the data of the correspondence between the pixel difference and the focusing compensation value according to the pixel difference obtained by the real-time image analysis unit, so as to convert the originally blurred defect pattern picture as a clear defect pattern picture.

In one embodiment of the present disclosure, the threshold is obtained through definition experiments and analyses of various in-line defect pattern pictures. In one embodiment of the present disclosure, the threshold is 10. The threshold may have a certain deviation. In one embodiment of the present disclosure, the deviation is within 20%, more preferably within 10%, even more preferably within 5%.

In summary, by embedding a real-time image analysis unit in a defect observation machine, analyzing and judging a defect pattern picture outputted by a defect observation unit in real time, and feeding back a focusing compensation value of a blurred defect pattern picture to the defect observation unit to perform focusing compensation on the blurred defect pattern picture, a clear photo is presented, thereby completing semiconductor product operations without artificial focusing for re-observation. The timeliness is high.

Finally, it should be noted that the above embodiments are only used for illustrating rather than limiting the technical solutions of the present disclosure. Although the present disclosure has been described in detail with reference to the foregoing embodiments, those ordinarily skilled in the art should understand that they can still modify the technical solutions recorded in the foregoing embodiments, or equivalently replace some or all of the technical features thereof; and such modifications or replacements do not deviate the essence of the corresponding technical solutions from the scope of the technical solutions of the embodiments of the present disclosure.

What is claimed is:

1. A defect observation machine having a function of analyzing and compensating for a defect pattern picture in real time so that the defect pattern picture outputted by the defect observation machine is a clear defect pattern picture, wherein the defect observation machine comprises:
a defect observation unit, which is used to perform defect pattern observation on a semiconductor product through a focusing value and output the defect pattern picture; and
a real-time image analysis unit, which is used to pre-store an average pixel value and data of a correspondence between a pixel difference and a focusing compensation value of a clear defect pattern picture, receive the defect pattern picture, perform data analysis on the defect pattern picture to obtain an average pixel value of the defect pattern picture, compare the average pixel value of the defect pattern picture and the average pixel value of the corresponding clear defect pattern picture to obtain a pixel difference, judge the pixel difference, output the received defect pattern picture as a final defect pattern picture if the absolute value of the pixel difference is less than or equal to a threshold, search for a corresponding focusing compensation value from the data of the correspondence between the pixel difference and the focusing compensation value according to the pixel difference if the absolute value of the pixel difference is greater than the threshold, output the focusing compensation value to the defect observation unit, such that the defect observation unit adjusts a focusing value of the defect observation unit by using the focusing compensation value and then keeps observing the same defect pattern and again outputs a defect pattern picture to the real-time image analysis unit.

2. The defect observation machine according to claim 1, wherein the defect observation unit is an electron microscope.

3. The defect observation machine according to claim 1, wherein the real-time image analysis unit selects 20% of a central portion of the received defect pattern picture, and obtains an average pixel value of the defect pattern picture within the range of 20% as the average pixel value of the defect pattern picture.

4. The defect observation machine according to claim 3, wherein the defect pattern picture within the range of 20% is divided into n*n units to obtain pixel values of the n*n units for converting the defect pattern picture within the range of 20% into data of luminance values of n*n pixels, so as to calculate an average value of pixel values of the data of luminance values of n*n pixels as the average pixel value of the defect pattern picture.

5. The defect observation machine according to claim 3, wherein the defect pattern picture within the range of 20% is divided into n*n units to obtain pixel values of the n*n units for converting the defect pattern picture within the range of 20% into a histogram with abscissas indicating luminance and ordinates indicating pixel values, so as to obtain the average pixel value of the defect pattern picture according to the histogram.

6. The defect observation machine according to claim 1, wherein the average pixel value of the clear picture of the defect pattern comprises average pixel values of clear pictures of the defect pattern of defects of 90% of all in-line defect types.

7. The defect observation machine according to claim 1, wherein an average pixel value of a blurred in-line defect pattern picture and an average pixel value of a clear defect pattern picture resulting from compensation are counted to obtain a pixel difference, and a focusing compensation value for compensating the blurred defect pattern picture as the clear defect pattern picture is counted, so as to obtain data of a correspondence between the pixel difference and the focusing compensation value.

8. The defect observation machine according to claim 1, wherein the pixel difference comprises a plurality of ranges wherein each corresponding to one focusing compensation value.

9. The defect observation machine according to claim 8, wherein when the pixel difference is negative, the focusing compensation value is positive, and when the pixel difference is positive, the focusing compensation value is negative.

10. The defect observation machine according to claim 1, wherein the threshold is obtained through definition experiments and analyses of various in-line defect pattern pictures.

11. The defect observation machine according to claim 1, wherein the threshold is 10.

12. An image analysis and compensation method of a defect observation machine, wherein the method comprises:
S1: a defect observation unit performing defect pattern observation on a semiconductor product through a focusing value, so as to output a defect pattern picture;
S2: a real-time image analysis unit receiving the defect pattern picture, and performing data analysis on the defect pattern picture to obtain an average pixel value of the defect pattern picture;
S3: pre-storing in the real-time image analysis unit an average pixel value of a clear picture of a defect pattern and data of a correspondence between a pixel difference and a focusing compensation value; and
S4: comparing the average pixel value of the defect pattern picture and the average pixel value of the corresponding clear picture of the defect picture to obtain a pixel difference, the real-time image analysis unit judging the pixel difference, the real-time image analysis unit outputting the received defect pattern picture as a final defect pattern picture if the absolute value of the pixel difference is less than or equal to a threshold, the real-time image analysis unit searching for a corresponding focusing compensation value from the data of the correspondence between the pixel difference and the focusing compensation value according to the pixel difference if the absolute value of the pixel difference is greater than the threshold, and outputting the focusing compensation value to the defect observation unit, such that the defect observation unit adjusts a focusing value of the defect observation unit by using the focusing compensation value and then keeps observing the same defect pattern and again outputs a defect pattern picture to the real-time image analysis unit.

13. The image analysis and compensation method of a defect observation machine according to claim 12, wherein the defect observation unit is an electron microscope.

14. The image analysis and compensation method of a defect observation machine according to claim 12, wherein the real-time image analysis unit selects 20% of a central portion of the received defect pattern picture, and obtains an average pixel value of the defect pattern picture within the range of 20% as the average pixel value of the defect pattern picture.

15. The image analysis and compensation method of a defect observation machine according to claim 14, wherein the defect pattern picture within the range of 20% is divided into n*n units to obtain pixel values of the n*n units for converting the defect pattern picture within the range of 20% into data of luminance values of n*n pixels, so as to calculate an average value of pixel values of the data of luminance values of n*n pixels as the average pixel value of the defect pattern picture.

16. The image analysis and compensation method of a defect observation machine according to claim 14, wherein the defect pattern picture within the range of 20% is divided into n*n units to obtain pixel values of the n*n units for converting the defect pattern picture within the range of 20% into a histogram with abscissas indicating luminance and ordinates indicating pixel values, so as to obtain the average pixel value of the defect pattern picture according to the histogram.

17. The image analysis and compensation method of a defect observation machine according to claim 12, wherein the average pixel value of the clear picture of the defect pattern comprises average pixel values of clear pictures of the defect pattern of defects of 90% of all in-line defect types.

18. The image analysis and compensation method of a defect observation machine according to claim 17, wherein average pixel values of the clear pictures of the defect pattern of defects of 90% of all defect types are obtained according to in-line data, and are pre-stored in the real-time image analysis unit as pre-stored average pixel values of the clear pictures of the defect pattern.

19. The image analysis and compensation method of a defect observation machine according to claim 12, wherein an average pixel value of a blurred in-line defect pattern picture and an average pixel value of a clear defect pattern picture resulting from compensation are counted to obtain a pixel difference, and a focusing compensation value for compensating the blurred defect pattern picture as the clear defect pattern picture is counted, so as to obtain data of a correspondence between the pixel difference and the focusing compensation value, and the data is pre-stored in the real-time image analysis unit as the data of the correspondence between the pixel difference and the focusing compensation value.

20. The image analysis and compensation method of a defect observation machine according to claim 12, wherein the pixel difference comprises a plurality of ranges wherein each corresponding to one focusing compensation value.

21. The image analysis and compensation method of a defect observation machine according to claim 20, wherein when the pixel difference is negative, the focusing compensation value is positive, and when the pixel difference is positive, the focusing compensation value is negative.

22. The image analysis and compensation method of a defect observation machine according to claim 12, wherein the threshold is obtained through definition experiments and analyses of various in-line defect pattern pictures.

23. The image analysis and compensation method of a defect observation machine according to claim 22, wherein the threshold is 10.
